(19) United States
(12) Patent Application Publication
(10) Pub. No.: US 2009/0077799 A1
(43) Pub. Date: Mar. 26, 2009

(54) Circuit board structure with capacitor embedded therein and method for fabricating the same

(75) Inventor: Chih Kui Yang, Sinfong Township (TW)

Correspondence Address: BACON & THOMAS, PLLC, 625 SLATERS LANE, FOURTH FLOOR, ALEXANDRIA, VA, 22314-1176, US

(73) Assignee: Phoenix Precision Technology Corporation, Hsinchu (TW)

(21) Appl. No.: 12/232,189

(22) Filed: Sep. 12, 2008

(30) Foreign Application Priority Data
Sep. 14, 2007 (TW) 096134560

(51) Int. Cl. H05K 1/18; H05K 3/10

(52) U.S. Cl. 29/846; 174/260

(57) ABSTRACT

The present invention relates to a circuit board structure with a capacitor embedded therein and the method for fabricating the same. The disclosed structure comprises: a core board; a buffer layer disposed on two surfaces of the core board and having a plurality of open areas; a first circuit layer disposed in the open areas; a high dielectric material film disposed over the first circuit layer and the buffer layer on at least one surface of the core board; and a second circuit layer disposed on the high dielectric material film, wherein the region where the second circuit layer corresponds to the first circuit layer functions as a capacitor, and the first circuit layer on two surfaces of the core board electrically connects to each other by at least one plated through hole. The present invention improves the problem of void generation and enhances the precision of the capacitor region.

### BACKGROUND OF THE INVENTION

1. Field of the Invention

The present invention relates to a circuit board structure with a capacitor embedded therein and a method for fabricating the same, and especially, to a circuit board structure with a capacitor embedded therein, in which the problem of void generation is improved, and a method for fabricating the same.

2. Description of Related Art

Owing to the rapid progress in semiconductor processing technology, and the upgrading performance of semiconductor chips, the manner of semiconductor devices has moved towards high integration. While semiconductor devices have become highly integrated, the number of I/O terminals such as input/output contact pads in a packaging structure also has increased. However, owing to the increased number of I/O terminals and highly dense circuit layouts, noise interference in a package structure now becomes greater than it was before. As a result, the amount of applied passive components (such as resistors, capacitors, and inductors) disposed in a semiconductor package structure may be increased generally to eliminate noise or compensate the performance. If elimination of noise and stabilization of performance are achieved, the packaged semiconductor chip can meet the requirements of electrical performance of semiconductor chips.

In conventional methods, a capacitor is generally mounted on a packaging substrate by surface mount technology (SMT). Currently, capacitors are formed by laminating a high dielectric material layer between copper layers, and then formation of circuits is performed. With reference to FIG. 1, a cross-section view of a capacitor formed by lamination is shown. As shown in FIG. 1, the structure includes an inner core board 11, a high dielectric material layer 12, an outer wiring layer 13, a plated through hole 14 and a solder mask 15. The inner core board 11 has an inner wiring layer 11a. Herein, the high dielectric material layer 12 is laminated on the inner core board 11 having the inner wiring layer 11a, followed by forming the outer wiring layer 13 thereon during the patterned circuits manufacturing process. In addition, a portion of the outer wiring layer 13 corresponds to the inner wiring layer 11a so that a capacitor 17 is formed in the region C. The plated through hole 14 extends through the inner core board 11 and electrically connects the circuits on both sides of the inner core board 11. Finally, the solder mask 15 is formed on the outmost wiring layer of the lamination structure.

However, since the high dielectric material layer is filled with a large amount of ceramic material (60 vol % or more), it results in poor fluidity of the high dielectric material. Due to the increased thickness of the circuits, the too-narrow gap between the circuits or the decreased thickness of the high dielectric material layer, voids inevitably occur during the filling process and result in trouble. Furthermore, the high dielectric material is also present between the inner circuits in the non-capacitor region. As a result, parasitic capacitance occurs between the circuits of the same wiring layer, and further results in signaling interference such as current leakage, especially in the application at high frequency. Accordingly, it is an important issue to overcome the aforementioned problems.

### SUMMARY OF THE INVENTION

In view of the drawbacks in prior arts, one object of the present invention is to provide a structure in which the generation of voids is inhibited in the process for depositing the high dielectric material between the circuits as well as a method for fabricating the same.

Another object of the present invention is to provide a structure in which the size precision of the electrode plate of the capacitor is enhanced as well as a method for fabricating the same.

Yet another object of the present invention is to provide a packaging substrate structure with fine lines.

To achieve the object, the present invention provides a circuit board structure with a capacitor embedded therein, comprising: a core board; a buffer layer disposed on two surfaces of the core board and having a plurality of open areas; a first circuit layer disposed in the open areas, wherein the whole surfaces of the first circuit layer and the buffer layer constitute a flat surface, and the first circuit layer comprises an inner wiring layer and an inner electrode layer; a high dielectric material film disposed over the first circuit layer and the buffer layer on at least one surface of the core board; and a second circuit layer disposed on the high dielectric material film, wherein the second circuit layer comprises an outer wiring layer and an outer electrode layer, the first circuit layer on each of the two opposite surfaces of the core board electrically connects to each other by at least one plated through hole, the outer wiring layer electrically connects to the inner wiring layer, and the outer electrode layer corresponds to the inner electrode layer to form a capacitor.

In addition, the present invention further provides a method for fabricating a circuit board structure with a capacitor embedded therein, comprising: providing a core board; forming a buffer layer on two opposite surfaces of the core board, wherein the buffer layer has a plurality of open areas; electroplating a first circuit layer comprising an inner wiring layer and an inner electrode layer in the open areas, and making the whole surfaces of the first circuit layer and the buffer layer constitute a flat surface; forming a high dielectric material film over the first circuit layer and the buffer layer on at least one surface of the core board; and forming a second circuit layer comprising an outer wiring layer and an outer electrode layer on the high dielectric material film, wherein the outer wiring layer electrically connects to the inner wiring layer, the outer electrode layer corresponds to the inner electrode layer to form a capacitor, and the first circuit layer on each of the two opposite surfaces of the core board electrically connects to each other by at least one plated through hole.

In the method for fabricating a circuit board structure with a capacitor embedded therein according to the present invention, the first and second circuit layers can be formed directly on the surfaces of the core board and the high dielectric material film, respectively. Alternatively, after a first seed layer and a second seed layer are respectively formed on the core board and the high dielectric material film, the first and second circuit layers are respectively formed on the first and second seed layers by an electroplating process.

In the circuit board structure with a capacitor embedded therein according to the present invention, the plated through hole can electrically connect the inner wiring layer on one surface of the core board with that on the other opposite surface thereof or/and the inner electrode layer on one surface of the core board with that on the other opposite surface thereof.

In the circuit board structure with a capacitor embedded therein according to the present invention, the outer wiring layer can electrically connect to the inner wiring layer through at least one conductive via, and the conductive via is disposed in the high dielectric material film. In addition, the conductive via can be partly or fully filled with conductive material.

In the circuit board structure with a capacitor embedded therein according to the present invention, the outer wiring layer can electrically connect to the inner wiring layer through at least one plated through hole, and the plated through hole extends through the core board and the high dielectric material film.

In the present invention, the type of the core board is not limited and can be an insulating board or a core board with inner circuits. In addition, the materials of the outer wiring layer, the inner wiring layer, the outer electrode layer and the inner electrode layer can be selected from the group consisting of copper, tin, nickel, chromium, titanium and lead. Preferably, copper is used.

In the present invention, the material of the buffer layer can be a photoimagable dielectric material. Preferably, the buffer layer of the present invention is made of a photoimagable dielectric material with low coefficient of thermal expansion (CTE) and low dielectric constant (Dk). In addition, the buffer layer of the present invention can be patterned by exposure and development to form a plurality of open areas. In comparison to the conventional method in which a wiring layer is formed and then high dielectric material is laminated thereon, the problem that voids occur in the process for depositing high dielectric material between circuits can be overcome by the method provided by the present invention, in which a buffer layer is formed and patterned to form open areas, and then a wiring layer is formed in the open areas. In addition, since the open areas of the buffer layer can be formed by exposure and development, the precision of the capacitor can be controlled accurately. Also, a structure with fine lines can be fabricated by controlling the size of the open areas of the buffer layer, and the problem that voids are generated in the process for depositing high dielectric material between circuits will not occur.

In the present invention, the material of the high dielectric material film can be selected from the group consisting of polymer material, ceramic material and polymer material filled with ceramic powders. Preferably, the high dielectric material film can be formed by dispersing a material selected from the group consisting of barium titanate, lead zicronate titanate, and amorphous hydrogenated carbon into a binder. The dielectric constant of the high dielectric material film is more than about 40. Preferably, the dielectric constant of the high dielectric material film ranges from 40 to 300.

Besides, the circuit board structure with a capacitor embedded therein according to the present invention can further comprise a built-up structure, which can be a single-layered or multi-layered structure. Herein, the built-up structure can be formed on the second circuit layer. The built-up structure can include a dielectric layer, a wiring layer and conductive vias. The conductive vias can electrically connect each wiring layer of the built-up structure, or electrically connect to the outer wiring layer in the circuit board structure with a capacitor embedded therein. In addition, the circuit board structure with a capacitor embedded therein according to the present invention can further comprise a solder mask on the surface of the built-up structure to protect the circuit board structure.

Accordingly, in the circuit board structure with a capacitor embedded therein and the method for fabricating the same provided by the present invention, the gap between circuits can be filled with a buffer layer beforehand by forming a buffer layer, patterning the buffer layer to form open areas, and then forming a wiring layer in the open areas, so that problems such as void generation caused by the insufficient amount of binder in the high dielectric material and the excessively low thickness thereof can be solved. In addition, the leakage caused by the parasitic capacitance between circuits of the same wiring layer also can be inhibited. Furthermore, since the buffer layer is patterned by exposure and development to define the areas of the capacitor regions, the precision of the capacitor regions can be more accurately controlled in comparison to the conventional method in which the capacitor regions are defined by etching the wiring layer. Also, a structure with fine lines can be fabricated by controlling the size of the open areas of the buffer layer, and the problem that voids are generated in the process for depositing high dielectric material between circuits will not occur.

Other objects, advantages, and novel features of the invention will become more apparent from the following detailed description when taken in conjunction with the accompanying drawings.

### BRIEF DESCRIPTION OF THE DRAWINGS

FIG. 1 shows a cross-section view of a conventional circuit board structure with a capacitor formed therein by lamination;

FIGS. 2A to 2F show cross-section views for illustrating a process of fabricating a circuit board structure with a capacitor embedded therein according to a preferred embodiment of the present invention;

FIG. 2F′ shows a cross-section view of a circuit board structure with a capacitor embedded therein according to another preferred embodiment of the present invention;

FIGS. 3A and 3B show cross-section views for illustrating a process of fabricating a circuit board structure with a capacitor embedded therein according to another preferred embodiment of the present invention;

FIG. 4 shows a cross-section view of a circuit board structure with a capacitor embedded therein according to a preferred embodiment of the present invention, in which a built-up structure is formed thereon;

FIGS. 5A and 5B show cross-section views for illustrating a process of fabricating a circuit board structure with a capacitor embedded therein according to another preferred embodiment of the present invention; and

FIG. 6 shows a cross-section view of a circuit board structure with a capacitor embedded therein according to another preferred embodiment of the present invention, in which a built-up structure is formed thereon.

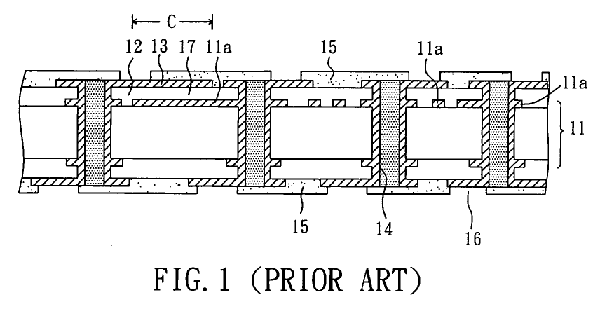

### DETAILED DESCRIPTION OF THE PREFERRED EMBODIMENT

Because of the specific embodiments illustrating the practice of the present invention, a person having ordinary skill in the art can easily understand other advantages and efficiency of the present invention through the content disclosed therein. The present invention can also be practiced or applied by other variant embodiments. Many other possible modifications and variations of any detail in the present specification based on different outlooks and applications can be made without departing from the spirit of the invention.

The drawings of the embodiments in the present invention are all simplified charts or views, and only reveal elements relative to the present invention. The elements revealed in the drawings are not necessarily aspects of the practice, and quantity and shape thereof are optionally designed. Further, the design aspect of the elements can be more complex.

### Embodiment 1

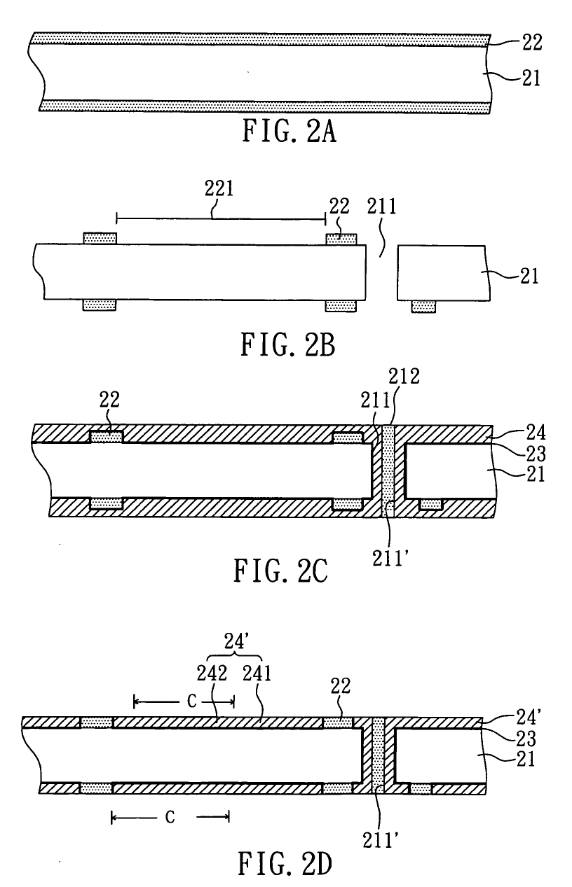

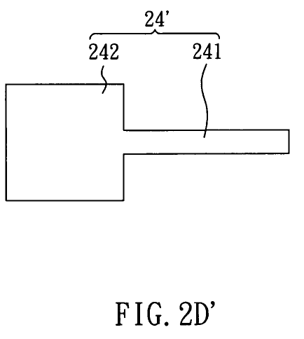

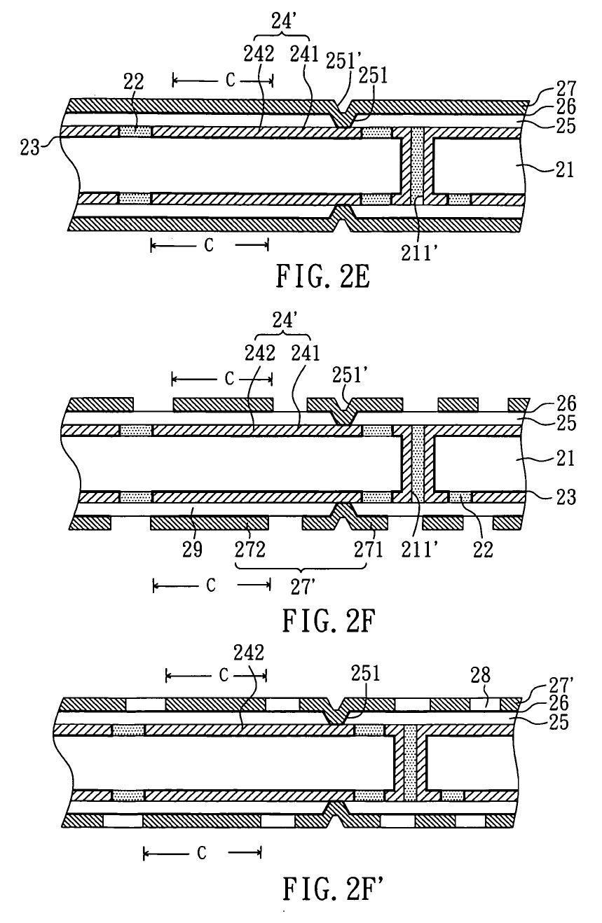

With reference to FIGS. 2A to 2F, there are shown cross-section views for illustrating a process of fabricating a circuit board structure with a capacitor embedded therein according to the present invention.

As shown in FIG. 2A, a core board 21 is first provided and then a buffer layer 22 is formed on two opposite surfaces of the core board 21 by one of coating, printing and attaching. Herein, the type of the core board 21 is not limited and can be an insulating board or a core board with inner circuits. In the present embodiment, the core board 21 is an insulating board, and the material of the buffer layer 22 is a photoimagable dielectric material.

Subsequently, as shown in FIG. 2B, an internal through hole 211 is formed in the core board 21 by laser ablation or mechanical drilling, and the buffer layer 22 is patterned by photolithography (i.e. exposure and development) to form a plurality of open areas 221.

As shown in FIG. 2C, a first seed layer 23 is formed on the surfaces of the core board 21 and the buffer layer 22 and the inner wall of the internal through hole 211 by electroless plating. The first seed layer 23 is a pathway for conducting current and required for a following electroplating process. Next, a first metal layer 24 is formed on the first seed layer 23 on the surfaces of the core board 21 and the buffer layer 22 and in the internal through hole 211 by electroplating to form a plated through hole 211′. Herein, the plated through hole 211′ is filled with an insulating resin 212. In the present embodiment, the materials of the first seed layer 23 and the first metal layer 24 can be selected from the group of copper, tin, nickel, chromium, titanium and lead. In the present embodiment, the first seed layer 23 and the first metal layer 24 are made of copper.

Next, as shown in FIG. 2D, the buffer layer 22 on the core board 21 is exposed by microetching or polishing to make the whole surfaces of the first circuit layer 24′ and the buffer layer 22 constitute a flat surface. Herein, the first circuit layer 24′ in the open areas includes an inner wiring layer 241 and an inner electrode layer 242, as shown in FIG. 2D′. In addition, the region with the inner electrode layer 242 disposed therein is defined as a capacitor region C.

As shown in FIG. 2E, a high dielectric material film 25 is formed on the surfaces of the first circuit layer 24′ and the buffer layer 22 by lamination. The high dielectric material film 25 can be made by dispersing a material selected from the group consisting of barium titanate, lead zicronate titanate, and amorphous hydrogenated carbon into a binder. For example, barium titanate can be dispersed in a binder to form the high dielectric material film 25 in the present embodiment. Besides, a via 251 is formed by laser ablation in the high dielectric material film 25. Sequentially, a second seed layer 26 is formed by electroless plating on the high dielectric material film 25 and in the via 251, and then a second metal layer 27 is formed by electroplating on the surface of the second seed layer 26. Accordingly, a conductive via 251′ can be formed in the via 251, which is partly filled with conductive material. The second seed layer 26 and the second metal layer 27 can be made of a material selected from the group consisting of copper, tin, nickel, chromium, titanium and lead. In the present embodiment, Cu is used. Finally, the second metal layer 27 and the second seed layer 26 covered thereby are etched to obtain a structure as shown in FIG. 2F, in which the second circuit layer 27′ includes an outer wiring layer 271 and an outer electrode layer 272. Accordingly, in the capacitor region C, the outer electrode layer 272 corresponds to the inner electrode layer 242 to form a capacitor 29. In addition, the conductive via 251′ is used to electrically connect the outer wiring layer 271 to the inner wiring layer 241. Hence, the circuit board structure with a capacitor embedded therein can be obtained by the abovementioned method.

Besides, the present embodiment also provides a structure as shown in FIG. 2F′. As shown in FIG. 2F′, a second seed layer 26 is formed by electroless plating on the surface of the high dielectric material film 25 and in the via 251. Subsequently, a patterned resist layer 28 is formed on the surface of the second seed layer 26. The resist layer 28 can be made of dry film or liquid photoresist. In the present embodiment, dry film is used. Then, a second circuit layer 27′ comprising the outer wiring layer 271 and the outer electrode layer 272 is formed by electroplating on the surface of the second seed layer 26 within the open areas of the patterned resist layer 28. Finally, the resist layer 28 and the second seed layer 26 covered thereby are removed to afford the circuit board structure with a capacitor embedded therein as shown in FIG. 2F′.

Accordingly, the circuit board structure with a capacitor embedded therein of the present invention as shown in FIG. 2F can be provided. The structure includes: a core board 21; a buffer layer 22 disposed on two opposite surfaces of the core board 21 and having a plurality of open areas; a first circuit layer 24′ disposed in the open areas, wherein the whole surfaces of the first circuit layer 24′ and the buffer layer 22 constitute a flat surface, and the first circuit layer 24′ includes an inner wiring layer 241 and an inner electrode layer 242; a high dielectric material film 25 disposed over the first circuit layer 24′ and the buffer layer 22; and a second circuit layer 27′ disposed on the high dielectric material film 25, wherein the second circuit layer 27′ includes an outer wiring layer 271 and an outer electrode layer 272. Herein, the first circuit layer 24′ on each of two opposite surfaces of the core board 21 electrically connects to each other by at least one plated through hole 211′, and the outer wiring layer 271 electrically connects to the inner wiring layer 241. In addition, the outer electrode layer 272 corresponds to the inner electrode layer 242 so as to form a capacitor 29.

### Embodiment 2

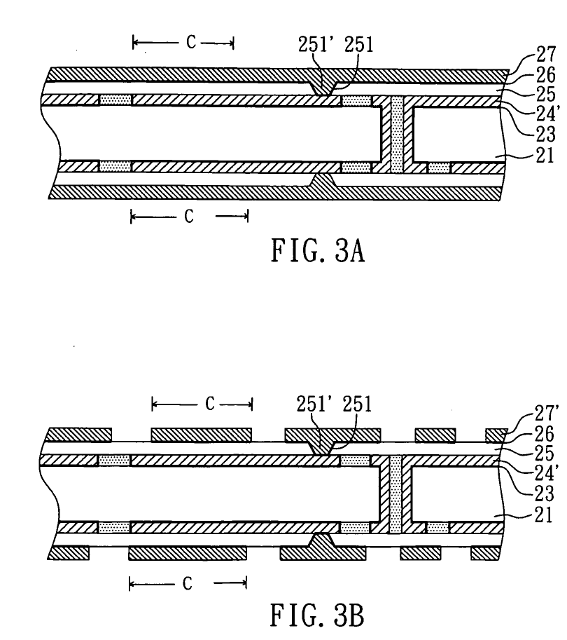

With reference to FIGS. 3A and 3B, there are shown cross-section views for illustrating a process of fabricating a circuit board structure with a capacitor embedded therein according to the present invention. The present embodiment is substantially similar to Embodiment 1, except that the via 251 is fully filled with conductive material in the process for forming the second metal layer 27 by electroplating, as shown FIG. 3A. Accordingly, the circuit board structure with a capacitor embedded therein, as shown in FIG. 3B, can be obtained by etching or the manner as shown in FIG. 2F′. As a result, the conductive via 251′ formed in the via 251 is fully filled with conductive material.

### Embodiment 3

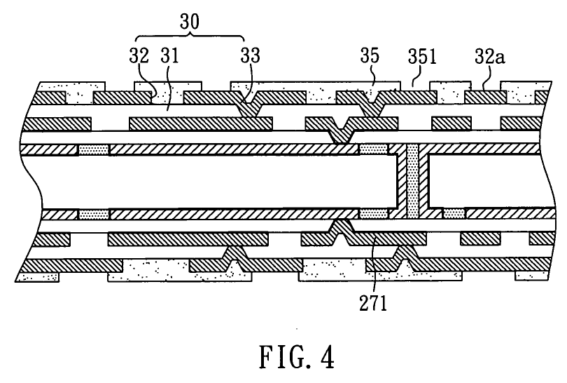

With reference to FIG. 4, a built-up structure shown in FIG. 4 can be formed on the surface of the circuit board structure with a capacitor embedded therein as manufactured in Embodiment 1. As shown in FIG. 4, the built-up structure 30 includes a dielectric layer 31, a wiring layer 32 stacked on the dielectric layer 31, and conductive vias 33 formed in the process for forming the wiring layer 32. The wiring layer 32 and the conductive vias 33 can be formed by the following process. First, a seed layer (not shown in FIG. 4) is formed on the dielectric layer 31. Subsequently, a resist layer (not shown in FIG. 4) is applied over the dielectric layer 31 with the seed layer thereon and patterned (not shown in FIG. 4) by exposure and development. Finally, a metal layer such as Cu is formed by electroplating on the seed layer, and then the resist layer and the seed layer thereunder are removed so as to form the wiring layer 32 and the conductive vias 33. Herein, the conductive vias 33 can be partly or fully filled with metal material. In the present embodiment, the conductive vias 33 are partly filled with metal material.

In the present invention, the built-up structure 30 can be a single-layered or multi-layered structure according to the requirement in the manufacture. In addition, the conductive vias 33 can electrically connect each wiring layer 32, or electrically connect to the outer wiring layer 271 in the circuit board structure with a capacitor embedded therein. The material of the dielectric layer 31 can be selected from Ajinomoto build-up film (ABF), bismaleimide triazine (BT), benzocyclobutene (BCB), liquid crystal polymer (LCP), polyimide (PI), poly(phenylene ether) (PPE), poly(tetrafluoroethylene) (PTFE), FR4, FR5, aramide, epoxy resin and glass fiber. In the present embodiment, ABF is used.

Furthermore, a solder mask 35 is further formed on the outermost surface of the built-up structure 30. The solder mask 35 has a plurality of openings 351 exposing portions of the wiring layer 32 of the built-up structure 30 serving as conductive pads 32a. Herein, solder balls (not shown in the figure) and solder bumps (not shown in the figure) can be further formed on the conductive pads 32a to electrically connect to electrode pads of a chip or other electronic devices.

### Embodiment 4

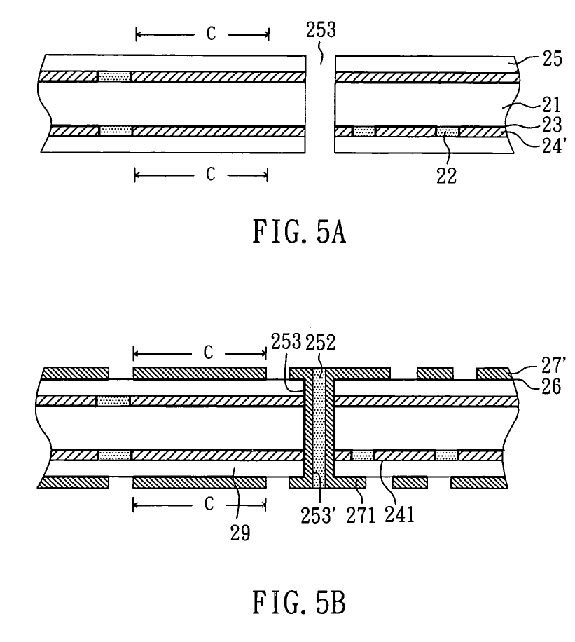

With reference to FIGS. 5A and 5B, there are shown cross-section views for illustrating a process of fabricating a circuit board structure with a capacitor embedded therein. The present example is substantially similar to Embodiment 1, except that the present embodiment uses a plated through hole to electrically connect the outer wiring layer with the inner wiring layer.

As shown in FIG. 5A, the process for forming a high dielectric material film 25 is the same as that illustrated in Embodiment 1, except that an inner through hole is not formed. Subsequently, the whole structure with the high dielectric material film 25 is perforated by mechanical drilling to form an external through hole 253.

Next, the second seed layer 26 and the second metal layer 27 are formed, and then the second metal layer 27 is patterned by etching, as shown in FIG. 2E. Alternatively, the resist layer 28 is patterned, and then the circuits are formed as shown in FIG. 2F′. Herein, a plated through hole 253′ is formed in the external through hole 253 in the process for forming the second circuit layer 27′. The plated through hole 253′ has a metal material layer formed on the inner wall thereof, and is filled with insulating resin 252. Accordingly, the structure with a capacitor 29 embedded therein, as shown in FIG. 5B, can be provided. In regard to the circuit board structure with a capacitor embedded therein of the present embodiment, the plated through hole 253′ can be used to electrically connect the outer wiring layer 271 with the inner wiring layer 241 on two surfaces of the core board.

### Embodiment 5

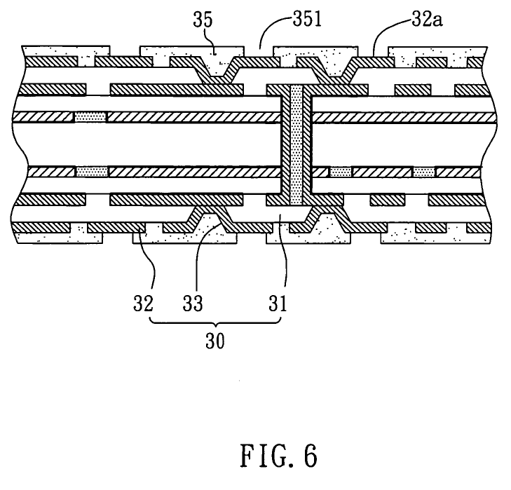

With reference to FIG. 6, a built-up structure 30 is formed on the surface of the circuit board structure with a capacitor embedded therein as manufactured in Embodiment 4. The built-up structure 30 can be formed in the same manner as in Embodiment 3.

Accordingly, in the present invention, the gap between circuits can be filled with a buffer layer made of photoimagable dielectric material beforehand, so that problems such as void generation caused by the insufficient amount of binder in the high dielectric material and the excessively low thickness thereof can be solved. In addition, since the buffer layer is patterned by exposure and development to define the areas of the capacitor region, the precision of the capacitor region can be enhanced. Moreover, the leakage caused by the parasitic capacitance can be inhibited due to no high dielectric material being laminated between circuits of the same wiring layer. Also, a structure with fine lines can be fabricated by controlling the size of the open areas of the buffer layer, and the problem that voids are generated in the process for depositing high dielectric material between circuits will not occur.

Although the present invention has been explained in relation to its preferred embodiment, it is to be understood that many other possible modifications and variations can be made without departing from the scope of the invention as hereinafter claimed.

What is claimed is:

1. A circuit board structure with a capacitor embedded therein, comprising:
a core board;
a buffer layer disposed on two surfaces of the core board and having a plurality of open areas;
a first circuit layer disposed in the open areas, wherein the whole surfaces of the first circuit layer and the buffer layer constitute a flat surface, and the first circuit layer comprises an inner wiring layer and an inner electrode layer;
a high dielectric material film disposed over the first circuit layer and the buffer layer on at least one surface of the core board; and
a second circuit layer disposed on the high dielectric material film, wherein the second circuit layer comprises an outer wiring layer and an outer electrode layer, the first circuit layer on each of the two opposite surfaces of the core board electrically connects to each other by at least one plated through hole, the outer wiring layer electrically connects to the inner wiring layer, and the outer electrode layer corresponds to the inner electrode layer to form a capacitor.

2. The circuit board structure with a capacitor embedded therein as claimed in claim 1, wherein the outer wiring layer electrically connects to the inner wiring layer through at least one conductive via, and the conductive via is disposed in the high dielectric material film.

3. The circuit board structure with a capacitor embedded therein as claimed in claim 2, wherein the conductive via is fully filled with conductive material.

4. The circuit board structure with a capacitor embedded therein as claimed in claim 2, wherein the conductive via is partly filled with conductive material.

5. The circuit board structure with a capacitor embedded therein as claimed in claim 1, wherein the outer wiring layer electrically connects to the inner wiring layer through at least one plated through hole, and the plated through hole extends through the core board and the high dielectric material film.

6. The circuit board structure with a capacitor embedded therein as claimed in claim 1, wherein the material of the buffer layer is a photoimagable dielectric material.

7. The circuit board structure with a capacitor embedded therein as claimed in claim 1, wherein the material of the high dielectric material film is selected from the group consisting of polymer material, ceramic material and polymer material filled with ceramic powders.

8. The circuit board structure with a capacitor embedded therein as claimed in claim 1, wherein the high dielectric material film has a dielectric constant in a range of from 40 to 300.

9. The circuit board structure with a capacitor embedded therein as claimed in claim 1, further comprising a built-up structure disposed on the second circuit layer.

10. The circuit board structure with a capacitor embedded therein as claimed in claim 1, further comprising a solder mask disposed on the surface of the built-up structure to protect the circuit board structure.

11. A method for fabricating a circuit board structure with a capacitor embedded therein, comprising:
providing a core board;
forming a buffer layer on two opposite surfaces of the core board, wherein the buffer layer has a plurality of open areas;
electroplating a first circuit layer comprising an inner wiring layer and an inner electrode layer in the open areas, and making the whole surfaces of the first circuit layer and the buffer layer constitute a flat surface;
forming a high dielectric material film over the first circuit layer and the buffer layer on at least one surface of the core board; and
forming a second circuit layer comprising an outer wiring layer and an outer electrode layer on the high dielectric material film, wherein the outer wiring layer electrically connects to the inner wiring layer, the outer electrode layer corresponds to the inner electrode layer to form a capacitor, and the first circuit layer on each of the two opposite surfaces of the core board electrically connects to each other by at least one plated through hole.

12. The method as claimed in claim 11, wherein the outer wiring layer electrically connects to the inner wiring layer through at least one conductive via, and the conductive via is formed in the high dielectric material film.

13. The method as claimed in claim 11, wherein the outer wiring layer electrically connects to the inner wiring layer through at least one plated through hole, and the plated through hole extends through the core board and the high dielectric material film.

14. The method as claimed in claim 11, further comprising:
forming a built-up structure on the second circuit layer.

15. The method as claimed in claim 14, further comprising:
forming a solder mask on the surface of the built-up structure.

16. The method as claimed in claim 11, wherein the material of the buffer layer is a photoimagable dielectric material.

17. The method as claimed in claim 16, wherein the open areas of the buffer layer are formed by exposure and development.

18. The method as claimed in claim 11, wherein the material of the high dielectric material film is selected from the group consisting of polymer material, ceramic material and polymer material filled with ceramic powders.
